(19) United States
(12) Patent Application Publication
(10) Pub. No.: US 2013/0320408 A1
(43) Pub. Date: Dec. 5, 2013

(54) SEMICONDUCTOR STRUCTURE AND FABRICATING METHOD THEREOF

(71) Applicants: Szu-Hung CHEN, Taoyuan County (TW); Hung-Min Chen, Kaohsiung (TW); Wen-Fa Wu, Hsinchu County (TW)

(72) Inventors: Szu-Hung CHEN, Taoyuan County (TW); Hung-Min Chen, Kaohsiung (TW); Wen-Fa Wu, Hsinchu County (TW)

(73) Assignee: National Applied Research Laboratories

(21) Appl. No.: 13/483,362

(22) Filed: May 30, 2012

(51) Int. Cl. H01L 29/78; H01L 21/336

(52) U.S. Cl. 257/288; 438/197; 257/E29.255; 257/E21.409

(57) ABSTRACT

A semiconductor device comprises a substrate, a metal-semiconductor compound layer and at least one kind of metal dopant. The substrate has a surface. The metal-semiconductor compound layer extends downwards into the substrate from the surface. The metal dopant which is made by one of a group of metal elements with atomic numbers ranging from 57 to 78 or the arbitrary combinations thereof and doped in the metal-semiconductor compound layer and the substrate with at least one peak concentration formed adjacent to the interface of the metal-semiconductor compound layer and the substrate.

### FIELD OF THE INVENTION

The present invention relates to a semiconductor structure and the method for fabricating the same, and more particularly to a method for fabricating a semiconductor structure having a metal-semiconductor compound layer and the applications thereof.

### BACKGROUND OF THE INVENTION

Parasitic resistances associated with the electrodes of a semiconductor device may limit device performance. The parasitic resistance effect may get worse, as the circuit critical dimensions continuing to shrinkage as well as the circuit integrity continuing to increase. Consequently, resistance-capacitance (RC) delay may occur, the improvement of device operating frequency may thus be limited, and the power loss may be increased.

For instance, while the critical dimension of a metal-oxide-semiconductor field effect transistor (MOSFET) is minimized to a nanometer size, the parasitic resistance including contact resistance and series resistance of the source/drain regions of the MOSFET with shallow junctions may become one of the major factors contributing to performance degradation. To reduce the parasitic resistance and improve the device operating speed and it's performance, silicidation technology has been utilized by the prior art in order to form a silicide layer on the gate electrode and the source/drain regions of the MOSFET, so as to decrease the sheet resistance of the gate electrode and the source/drain regions.

However, contact resistance occurring on the interface of the silicide layer and the source/drain regions may conversely decrease the current flow of the MOSFET and deteriorate its total performance. Therefore, how to solve the problems due to the high contact resistance occurs between the silicide layer and the source/drain regions is still a challenge to the industry and persons having ordinary skill in the art.

### SUMMARY OF THE INVENTION

Therefore, one aspect of the present invention is to provide a semiconductor structure, wherein the semiconductor structure comprises a substrate, a metal-semiconductor compound layer and at least one kind of metal dopants. The substrate has a surface. The metal-semiconductor compound layer extends downwards into the substrate from the surface. The metal dopant is made by one of a group of metal elements with atomic numbers ranging from 57 to 78 or the arbitrary combinations thereof and doped in the metal-semiconductor compound layer and the substrate with at least one peak concentration formed adjacent to the interface of the metal-semiconductor compound layer and the substrate.

In one embodiment of the present invention, the substrate consists of silicon (Si), germanium (Ge), Silicon-Germanium (Si—Ge) or the arbitrary combinations thereof

In one embodiment of the present invention, the semiconductor structure further comprises a gate dielectric layer disposed on the substrate, a gate electrode disposed on the gate dielectric layer and a source/drain structure formed in the substrate and adjacent to the gate dielectric layer, wherein the metal-semiconductor compound layer extends downwards into the source/drain structure from the surface of the substrate.

In one embodiment of the present invention, the source/drain structure is doped with n-type dopants, and the metal elements are selected from a group consisting of cerium (Ce), praseodymium (Pr), samarium (Sm), europium (Eu), gadolinium (Gd), terbium (Tb), dysprosium (Dy), holmium (Ho), erbium (Er), thulium (Tm) and ytterbium (Yb) the arbitrary combinations thereof.

In one embodiment of the present invention, the source/drain structure is doped with p-type dopants, and the metal elements are selected from a group consisting of rhenium (Re), osmium (Os), iridium (Ir), platinum (Pt) and the arbitrary combinations thereof.

Another aspect of the present invention is to provide a method for fabricating a semiconductor structure, wherein the method comprises steps as follows: Firstly, a substrate is provided and a metal-semiconductor compound layer is then formed extending downwards into the substrate from a surface of the substrate. Subsequently, at least one metal dopant which is made by one of a group of metal elements with atomic numbers ranging from 57 to 78 or the arbitrary combinations thereof is implanted into the substrate and the metal-semiconductor compound layer, so as to form at least one peak concentration of the metal dopant adjacent to the interface of the metal-semiconductor compound layer and the substrate.

In one embodiment of the present invention, prior to the formation of the metal-semiconductor compound layer, the method further comprises steps of forming a gate dielectric layer on the substrate; forming a gate electrode on the gate dielectric layer; and forming a source/drain structure in the substrate and adjacent to the gate dielectric layer.

In one embodiment of the present invention, the source/drain structure is doped with n-type dopants, and the metal elements implanted into the substrate and the metal-semiconductor compound layer are selected from a group consisting of Ce, Pr, Sm, Eu, Gd, Tb, Dy, Ho, Er, Tm, Yb and the arbitrary combinations thereof.

In one embodiment of the present invention, the source/drain structure is doped with p-type dopants, and the metal elements implanted in the substrate and the metal-semiconductor compound layer are selected from a group consisting of Re, Os, Ir, Pt and the arbitrary combinations thereof.

In one embodiment of the present invention, the formation of the metal-semiconductor compound layer comprises steps of forming a metal layer on the surface of the substrate, performing a thermal annealing process on the metal layer and then removing the remaining metal layer.

In one embodiment of the present invention, the step of implanting the metal elements into the substrate and the metal-semiconductor compound layer comprises performing a metal doping process to dope the metal dopant into the substrate prior to the formation of the metal-semiconductor compound layer.

In one embodiment of the present invention, the step of implanting the metal elements into the substrate and the metal-semiconductor compound layer comprises performing a metal doping process to dope the metal dopant into the substrate after the metal-semiconductor compound layer is formed.

In one embodiment of the present invention, the method for fabricating a semiconductor structure further comprises steps of forming a MOSFET on the substrate and implanting the metal dopant into a source region and a drain region of the MOSFET prior to the formation of the metal-semiconductor compound layer.

In accordance with aforementioned embodiments, a semiconductor structure and the method for fabricating the same are provided, wherein at least one kind of metal dopants made by one of a group of metal elements with atomic numbers ranging from 57 to 78 or the arbitrary combinations thereof are implanted into a substrate and a metal-semiconductor compound layer formed in the substrate, so as to form a predetermined concentration distribution of the metal dopant adjacent to the interface of the metal-semiconductor compound layer and the substrate used to adjust the energy barrier occurring at the interface, whereby the parasitic resistance of the semiconductor device can be reduced and meanwhile the performance of the semiconductor device adopting the semiconductor structure can be increased.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A through 1E illustrate cross-sectional views of a method for fabricating a MOSFET device having a metal-semiconductor compound layer in accordance with one embodiment of the present invention.

FIG. 2 illustrates a secondary ion mass spectrometry (SIMS) molecular depth profile of a drain region disposed in a substrate in accordance with one embodiment of the present invention.

FIG. 3 is an electric characteristic illustrating the result of a current density/voltage analysis subject to a diode composed of a metal-semiconductor compound layer and an n-type substrate in accordance with one embodiment of the present invention.

### DETAILED DESCRIPTION OF PREFERRED EMBODIMENTS

A semiconductor device having a metal-semiconductor compound layer and the method for fabricating the same are provided, by which the energy barrier forming at the interface can be adjust, so as to reduce the contact resistance forming at the interface of a substrate and the metal-semiconductor compound layer and increase the performance of the semiconductor device as well. The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

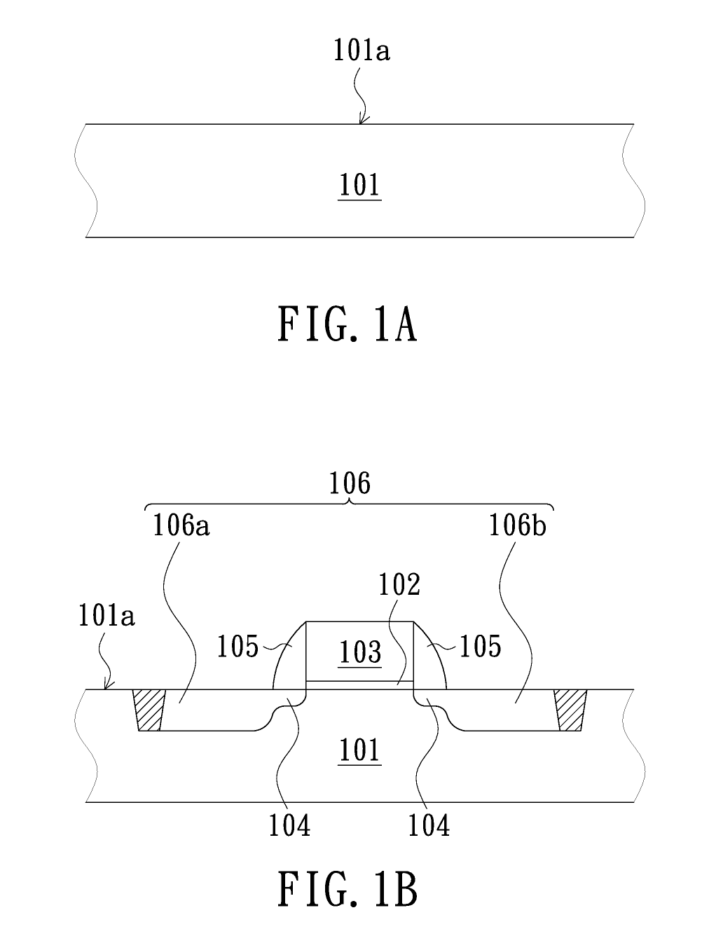

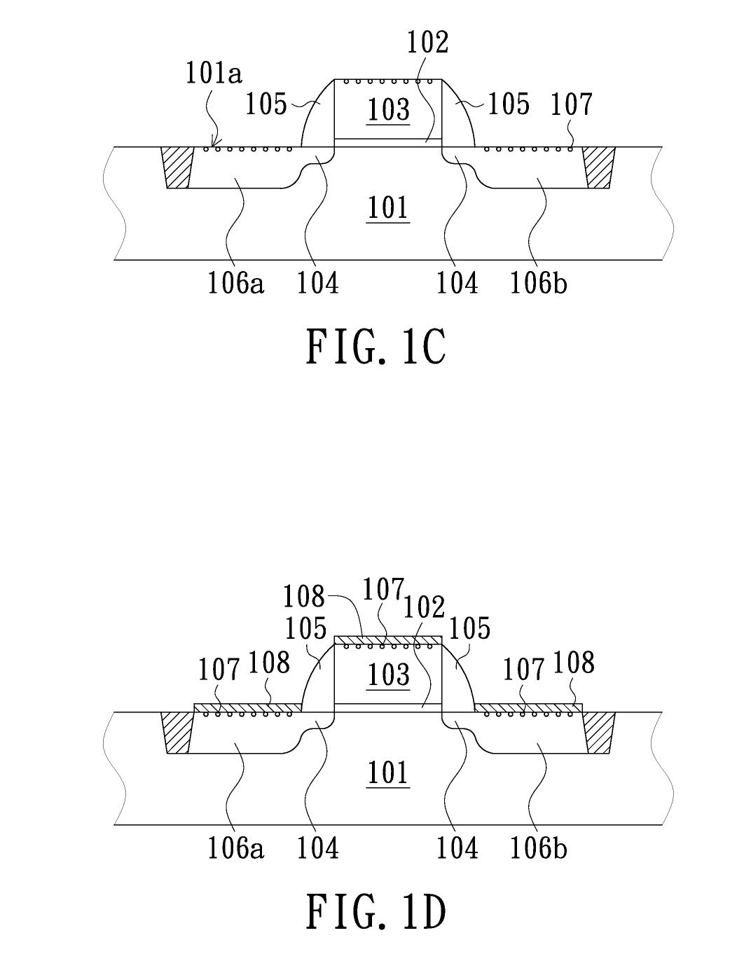

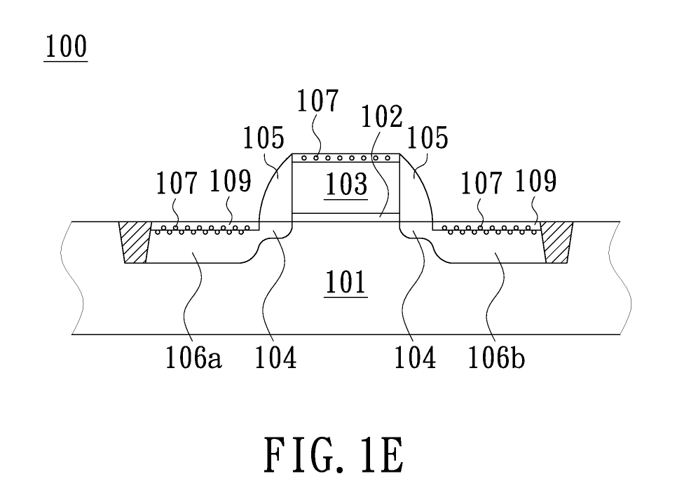

FIGS. 1A through 1E illustrate cross-sectional views of a method for fabricating a MOSFET device 100 having a metal-semiconductor compound layer 109 in accordance with one embodiment of the present invention. Wherein the method for fabricating the MOSFET device 100 comprises steps as follows:

Firstly, a substrate 101 is provided (see FIG. 1A). In some embodiments of the present invention, the substrate 101 is made of Si, Ge Si—Ge or the arbitrary combinations thereof. In the present embodiment, the substrate 101 is made of Si.

The provision of the substrate 101 comprises a doping process in order to change the polarity of the substrate 101. In some embodiments of the present invention, phosphor (P) ions, arsenic (As) ions, or stibium (Sb) ions may be implanted into the substrate 101 by the doping process to render the substrate 101 having an n-type polarity. In some other embodiments of the present invention, boron (B) ions, indium (In) ions or gallium (Ga) ions are alternatively implanted into the substrate 101 by the doping process to render the substrate 101 having a p-type polarity.

Next, a gate dielectric layer 102 and a gate electrode 103 are formed on a surface 101a of the substrate 101 in sequence by a series deposition and lithographic processes. A light doped drain (LDD) structure 104 is then formed in the substrate 101 adjacent to the gate dielectric layer 102 by a plurality of light ion doping processes using the gate dielectric layer 102 and the gate electrode 103 as masks; and a spacer 105 is formed to cover the sidewalls of the gate dielectric layer 102 and the gate electrode 103 after the LDD structure 104 is formed. Subsequently, a series of ion doping processes are performed on the LDD structure 104 by using the spacer 105, the gate dielectric layer 102 and the gate electrode 103 as masks to define a source/drain structure 106 extending downwards into the substrate 101 from the surface 101a of the substrate 101 (see FIG. 1B). In the present embodiment, the source/drain structure 106 is composed of an n-type source region 106b and an n-type drain region 106a. However in another embodiment, the source/drain structure 106 may be otherwise composed by a p-type source region 106b and a p-type drain region 106a.

After the formation of the source/drain structure 106, a metal doping process is performed to implant at least one metal dopant 107 into the substrate 101 (see FIG. 1C), wherein the metal dopant 107 is made by one of a group of metal elements having atomic numbers ranging from 57 to 78 or the arbitrary combinations thereof.

The selection of the metal dopant 107 comprises choosing suitable metal elements in accordance with the polarity of the substrate 101 (e.g. in accordance with the polarity of the source region 106b and the drain region 106a respectively). In some embodiments of the present invention, when the substrate 101 (the source region 106b and the drain region 106a) is doped with n-type dopants, metal elements such as Ce, Pr, Sm, Eu, Gd, Tb, Dy, Ho, Er, Tm, Yb or the arbitrary combinations thereof may be selected as the metal dopant 107 for implanting into the substrate 101 (the source region 106b and the drain region 106a respectively). In some other embodiments of the present invention, when the substrate 101 (the source region 106b and the drain region 106a) is doped with p-type dopants respectively, metal elements such as Re, Os, Ir, Pt, Tm, Yb or the arbitrary combinations thereof may be selected as the metal dopant 107 implanting into the substrate 101 (the source region 106b and the drain region 106a). Preferably, when the source region 106b and the drain region 106a are doped with p-type dopants, metal elements Pt may be selected as the metal dopant 107 for implanting into the source region 106b and the drain region 106a respectively. Alternatively, in the present embodiment, metal elements Yb is selected to be implanted into the source region 106b and the drain region 106a which are respectively doped with n-type dopants.

Subsequently, a metal deposition process is performed to form a metal layer 108 on the gate electrode 103 and the source/drain structure 106 (see FIG. 1D). In the present embodiment, the metal layer 108 is made of cobalt (Co), nickel (Ni) or Co—Ni alloy.

Thereafter, a thermal annealing process is performed to trigger a silicidation on the metal layer 108 disposed on the source/drain structure 106, so as to form a silicide layer (metal-semiconductor compound layer) 109 extending downwards into the source/drain structure 106 from the surface 101a of the substrate 101. The remaining metal layer 108 which is not subjected to the silicidation is then removed, meanwhile the MOSFET device 100 is formed (see FIG. 1E).

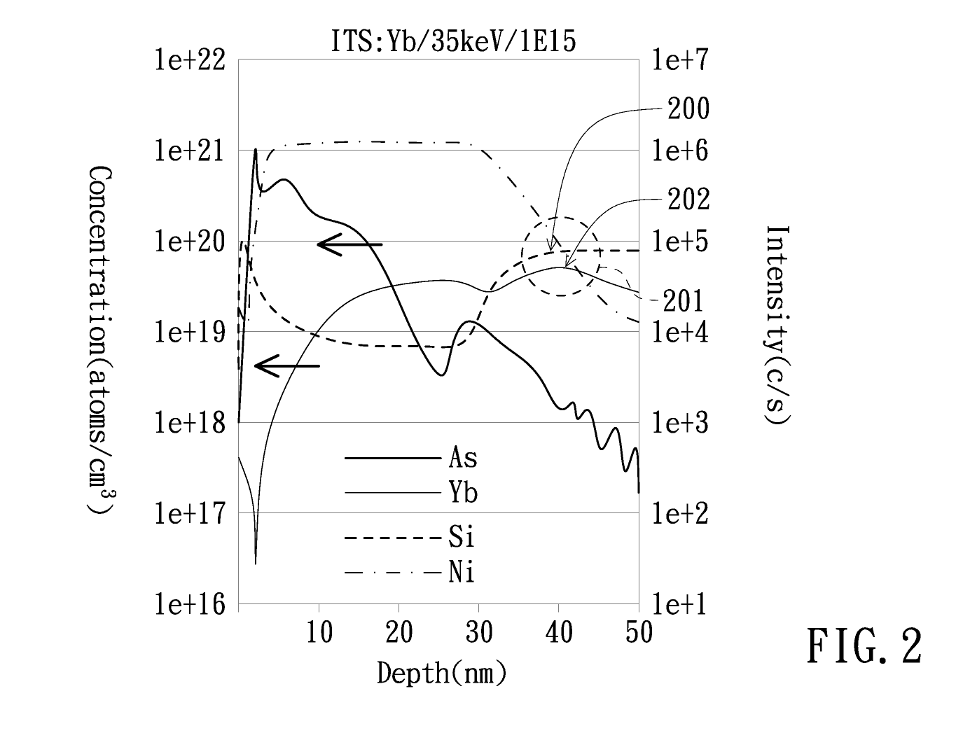

It should be appreciated that the metal dopant 107 formerly implanted in the source/drain structure 106 can be further driven into the substrate 101 by the thermal annealing process simultaneous to the silicidation for forming the silicide layer 109, whereby at least one peak concentration of the metal dopant 107 can be formed on the region adjacent to the interface of the silicide layer 109 and the source region 106b or the interface of the silicide layer 109 and the drain region 106a. In the present embodiment, a concentration peak 202 of the metal dopant 107 (see FIG. 2) is formed on the regions 201 adjacent to the interface of the silicide layer 109 and the source region 106b.

However, in some other embodiments of the present invention, the metal doping process may be performed after the formation of the silicide layer 109. In this case, the metal layer 108 is firstly formed on the gate electrode 103 and the source/drain structure 106; the thermal annealing process is then carried out; and after the remaining metal layer 108 is removed, the metal doping process is performed to directly implant the metal dopant 107 into the substrate 101 and the silicide layer 109, whereby at least one concentration peak of the metal dopant 107 may be formed on the regions adjacent to the interfaces of the silicide layer 109 and the source/drain structure 106. The concentration profile of the metal dopant 107 is preferably conformed to a Gaussian distribution.

FIG. 2 illustrates a SIMS depth profile of the drain region 106a disposed in the substrate 101 in accordance with one embodiment of the present invention, wherein the X-axis of the molecular depth profile indicates the depth (nm) of the drain region 106a; the Y-axis indicates the doping concentration (cm⁻³) and the dopant intensity (c/s); and the intersection of the distribution curves of Si and Ni indicates the interface 200 of the silicide layer 109 and the drain region 106a. In the present embodiment, a bell-shaped concentration profile of metal elements Yb implanted into the drain region 106a of the substrate 101 having a mean value or peak 202 is formed on the region 201 adjacent to the interface 200 of the silicide layer 109 and the drain region 106a. The bell-shaped concentration profile formed adjacent to the interface 200 of the silicide layer 109 and the drain region 106a is substantially conformed to a Gaussian distribution.

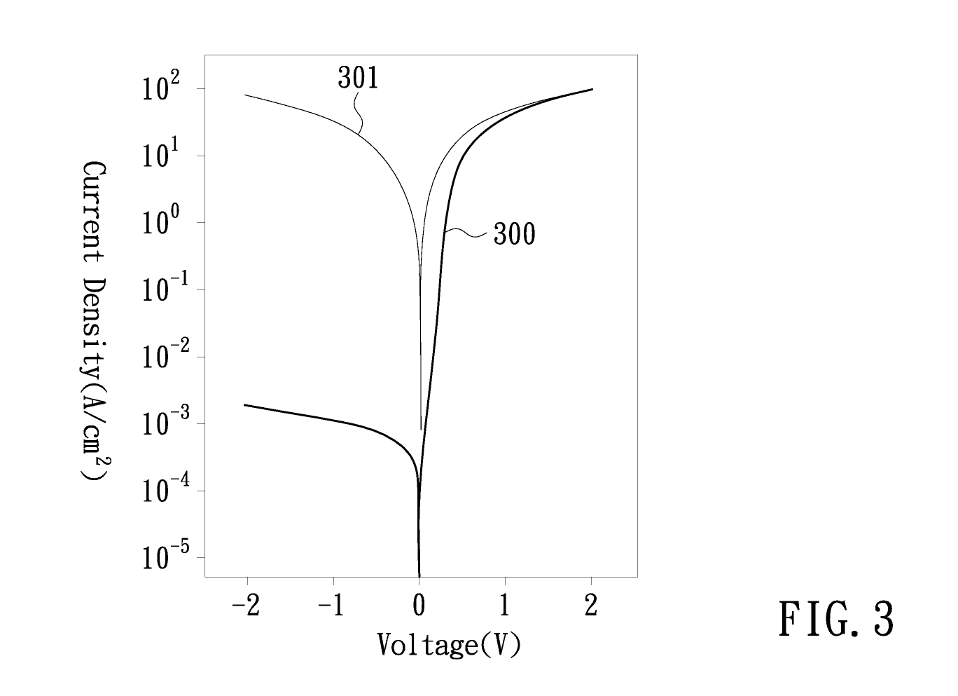

FIG. 3 is a curve diagram illustrating the result of a current density/voltage analysis subject to a diode composed by a metal-semiconductor compound layer (such as the silicide layer 109) and an n-type substrate (such as the drain region 106a) in accordance with one embodiment of the present invention, wherein the X-axis indicates the voltage (V); the Y-axis indicates current density (A/cm²); the curve 300 indicates the current density/voltage characteristic of the metal-semiconductor compound layer (the silicide layer) which are not doped with the metal dopant 107 serving as control groups; and the curve 301 indicates the current density/voltage characteristic of the metal-semiconductor compound layer (the silicide layer 109) doped with Yb (the metal dopant 107).

In comparison with the curve 300 of the control groups, the curve 301 reveal that there is a 10⁵-fold increase in the current density passing through the silicide layer 109 doped with Yb. It is apparent that, the implantation of Yb (the metal dopant 107) has the benefit of the reduction of Schottky barrier occurring on the interface 200 of the metal-semiconductor compound layer (the silicide layer 109) and the n-type substrate (the drain region 106a), by which the contact resistance generated between the metal-semiconductor compound layer and the n-type substrate can be reduced, the parasitic resistance of the MOSFET device 100 can be reduced, and meanwhile the performance of the MOSFET device 100 can be improved.

In accordance with aforementioned embodiments, a semiconductor structure and the method for fabricating the same are provided, wherein at least one kind of metal dopant made by one of a group of metal elements with atomic numbers ranging from 57 to 78 or the arbitrary combinations thereof are implanted into a substrate and a metal-semiconductor compound layer formed in the substrate, so as to form a predetermined concentration distribution of the metal dopant adjacent to the interface of the metal-semiconductor compound layer and the substrate used to adjust the energy barrier occurring at the interface, whereby the parasitic resistance of the semiconductor structure can be reduced and meanwhile the performance of a semiconductor device adopting the semiconductor structure can be increased.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A semiconductor device comprises:
a substrate having a surface;
a metal-semiconductor compound layer, extending downwards into the substrate from the surface; and
at least one kind of metal dopant, made by one of a group of metal elements with atomic numbers ranging from 57 to 78 or the arbitrary combinations thereof and doped in the metal-semiconductor compound layer and the substrate with at least one peak concentration formed adjacent to the interface of the metal-semiconductor compound layer and the substrate.

2. The semiconductor device according to claim 1, wherein the substrate consists of silicon (Si), germanium (Ge), Silicon-Germanium (Si—Ge) or the arbitrary combinations thereof.

3. The semiconductor device according to claim 1, further comprising:
a gate dielectric layer, disposed on the substrate;
a gate electrode, disposed on the gate dielectric layer; and
a source/drain structure formed in the substrate and adjacent to the gate dielectric layer, wherein the metal-semiconductor compound layer extends downwards into the source/drain structure from the surface of the substrate.

4. The semiconductor device according to claim 3, wherein the source/drain structure is doped with n-type dopants.

5. The semiconductor device according to claim 4, wherein the metal elements are selected from a group consisting of cerium (Ce), praseodymium (Pr), samarium (Sm), europium (Eu), gadolinium (Gd), terbium (Tb), dysprosium (Dy), holmium (Ho), erbium (Er), thulium (Tm), ytterbium (Yb) and the arbitrary combinations thereof.

6. The semiconductor device according to claim 3, wherein the source/drain structure is doped with p-type dopants.

7. The semiconductor device according to claim 6, wherein the metal elements are selected from a group consisting of rhenium (Re), osmium (Os), iridium (Ir), platinum (Pt) and the arbitrary combinations thereof.

8. A method for fabricating a semiconductor device, comprising steps as follows:
providing a substrate;
forming a metal-semiconductor compound layer extending downwards into the substrate from a surface of the substrate; and
implanting at least one kind of metal dopant which is made by one of a group metal elements with atomic numbers ranging from 57 to 78 or the arbitrary combinations thereof into the substrate and the metal-semiconductor compound layer, so as to form at least one peak concentration of the metal dopant adjacent to the interface of the metal-semiconductor compound layer and the semiconductor substrate.

9. The method according to claim 8, further comprising:
forming a gate dielectric layer on the substrate;
forming a gate electrode on the gate dielectric layer; and
forming a source/drain structure in the substrate and adjacent to the gate dielectric layer, prior to the formation of the metal-semiconductor compound layer.

10. The method according to claim 8, wherein the source/drain structure is doped with n-type dopants.

11. The method according to claim 10, wherein the metal elements implanted into the substrate and the metal-semiconductor compound layer are selected from a group consisting of Ce, Pr, Sm, Eu, Gd, Tb, Dy, Ho, Er, Tm, Yb and the arbitrary combinations thereof.

12. The method according to claim 8, wherein the source/drain structure is doped with p-type dopants.

13. The method according to claim 12, wherein the metal elements implanted in the substrate and the metal-semiconductor compound layer are selected from a group consisting of Re, Os, Ir, Pt and the arbitrary combinations thereof.

14. The method according to claim 8, wherein the formation of the metal-semiconductor compound layer comprises:
forming a metal layer on the surface of the substrate;
performing a thermal annealing process on the metal layer; and
removing the remaining metal layer.

15. The method according to claim 14, wherein the step of implanting the metal elements into the substrate and the metal-semiconductor compound layer comprises performing a metal doping process to dope the metal dopant into the substrate prior to the formation of the metal-semiconductor compound layer.

16. The method according to claim 8, wherein the step of implanting the metal elements into the substrate and the metal-semiconductor compound layer comprises performing a metal doping process to dope the metal dopant into the substrate after the metal-semiconductor compound layer is formed.

17. The method according to claim 8, wherein prior the metal-semiconductor compound layer is formed, the method further comprises:
forming a metal-oxide-semiconductor field effect transistor (MOSFET) on the substrate; and
implanting the metal dopant into a source region and a drain region of the MOSFET.
